(19) United States
(12) Patent Application Publication
(10) Pub. No.: US 2022/0278587 A1
(43) Pub. Date: Sep. 1, 2022

(54) ELECTRONIC CONTROL UNIT

(71) Applicant: HITACHI ASTEMO, LTD., Hitachinaka-shi, Ibaraki (JP)

(72) Inventor: Haruaki MOTODA, Hitachinaka (JP)

(73) Assignee: HITACHI ASTEMO, LTD., Hitachinaka-shi, Ibaraki (JP)

(21) Appl. No.: 17/627,879

(22) PCT Filed: Aug. 14, 2020
(86) PCT No.: PCT/JP2020/030858

§ 371 Date: Jan. 18, 2022

(30) Foreign Application Priority Data
Sep. 24, 2019 (JP) 2019-173478

(51) Int. Cl. H02K 5/22; H05K 7/14; B62D 5/04; H05K 1/18; H02K 11/33

(52) U.S. Cl. CPC H02K 5/225; H05K 7/1432; B62D 5/0406; H05K 1/181; H02K 11/33

(57) ABSTRACT

Provided is an electronic control unit that can be downsized. An electronic control unit 30 includes: a board module 0 in which an electric circuit is formed on on a board 51; and a connector module 80 in which a conductive wiring structure 100 is held in a base 81 having a plane surface 83 to enable electric connection between the electric circuit of the board module 50 and an external device via the wiring structure 100. The wiring structure 100 of the connector module 80 has portions exposed toward the plane surface 83 of the base 81. The connector module 80 has electronic components 92, 93, 96, 97, and 98 bonded to the wiring structure 100 in a state where they are placed on the plane surface 83 of the base 81.

### TECHNICAL FIELD

The present invention relates to an electronic control unit, and more particularly to, an electronic control unit including a connector enabling electrical connection to an external device such as a power supply.

### BACKGROUND ART

An electronic control unit of an electric power steering or the like generally includes a module including a connector enabling electrical connection to an external device such as a power supply, and a circuit board including various circuits for controlling a control target, converting power, and the like. In some of such electronic control units, there is provided a module where a conductive member connected to the circuit board is integrally molded with the connector, while an electronic component is connected to the conductive member (for example, see PTL1). In a control device described in PTL 1, a conductor module is formed by integrally molding a bus bar (plate-shaped conductive member) and a connector by molding, and connecting an electronic component to the bus bar.

### CITATION LIST

### Patent Literature

PTL 1: JP 2006-21552 A

### SUMMARY OF INVENTION

### Technical Problem

In the control device described in PTL 1, a structure for connecting the electronic component to the bus bar is as follows. A hole is formed in the bottom of the conductor module provided with the bus bar, and a terminal of the electronic component is inserted into the hole in the bottom. Further, the terminal of the electronic component inserted into and protruding from the hole is connected to a terminal of the bus bar protruding from the bottom of the conductor module by welding. In such a structure for connecting the electronic component and the bus bar to each other, a lead portion for connecting the electronic component to the bus bar needs to have a certain-degree length, and accordingly, it is necessary to secure a corresponding space for the connection between the electronic component and the bus bar. Therefore, such a module, in which the electronic component is connected to the bus bar integrally molded with the connector, needs to be further downsized.

In particular, as automatic driving technology has recently progressed, redundant systems may be adopted for various systems so that driving can be continued even if a failure occurs in a component. An in-vehicle electronic control unit may also include at least dual control systems, considering that a failure occurs in an electronic component, a wiring is short-circuited, or the like. In this case, electronic components are also at least doubly mounted on a board, and mounting spaces therefor are required accordingly. Meanwhile, in order to secure a space in the interior of a vehicle and because of an increase in the number of components in an engine room, a space in the engine room has becoming small. Therefore, even an electronic control unit adopting redundant systems needs to be downsized.

The present invention has been made in order to solve the above problems, and an object of the present invention is to provide an electronic control unit that can be downsized.

### Solution to Problem

The present application has a plurality of means of solving the above problems; however, according to one of preferred modes of the present invention, an electronic control unit includes: a board module in which an electric circuit is formed on a board; and a connector module in which a conductive wiring structure is held in a base having a plane surface to enable electric connection between the electric circuit of the board module and an external device via the wiring structure. The wiring structure of the connector module has portions exposed toward the plane surface of the base, and the connector module has electronic components bonded to the wiring structure in a state where the electronic components are placed on the plane surface of the base.

### Advantageous Effects of Invention

According to the present invention, since the electronic components are bonded to the wiring structure in a state where the electronic components are placed on the plane surface of the base of the connector module, only spaces for placing the electronic components are required at the time of bonding the electronic components, and it is not necessary to secure extra spaces for securing bonding portions between the electronic components and the wiring structure. Therefore, downsizing can be achieved.

Other problems, configurations, and effects that are not described above will be apparent from the following description of embodiments.

### BRIEF DESCRIPTION OF DRAWINGS

FIG. 1 is a perspective view illustrating an electric power steering device including an electronic control unit according to one embodiment of the present invention.

FIG. 2 is a block diagram illustrating an electric system configuration of an electric drive device including an electronic control unit according to one embodiment of the present invention.

FIG. 3 is a circuit diagram illustrating a configuration of a power supply circuit unit illustrated in FIG. 2.

FIG. 4 is a perspective view illustrating an electric drive device including an electronic control unit according to one embodiment of the present invention in a partially exploded state.

FIG. 5 is a longitudinal sectional view illustrating a structure of an electronic control unit according to one embodiment of the present invention.

FIG. 6 is a schematic view illustrating a configuration and arrangement of electronic components of a board module constituting a part of an electronic control unit according to one embodiment of the present invention.

FIG. 7 is a perspective view illustrating a connector module constituting a part of an electronic control unit according to one embodiment of the present invention, in a state where a connector base of the connector module is transparent.

FIG. 8 is a plan view of a connector module constituting a part of an electronic control unit according to one embodiment of the present invention when viewed from above connector units.

FIG. 9 is a plan view of a connector module constituting a part of an electronic control unit according to one embodiment of the present invention when viewed from a surface on which electronic components are mounted.

FIG. 10 is a view illustrating the connector module illustrated in FIG. 9 in a state where a connector base is transparent.

FIG. 11 is a transparent view illustrating the arrangement of wiring structures in the connector module illustrated in FIG. 10 in a state where the electronic components are eliminated.

FIG. 12 is an explanatory diagram illustrating an example of a general method of mounting an electronic component on a board.

FIG. 13 is a schematic diagram illustrating a method of mounting an electronic component on a connector module constituting a part of an electronic control unit according to one embodiment of the present invention.

### DESCRIPTION OF EMBODIMENTS

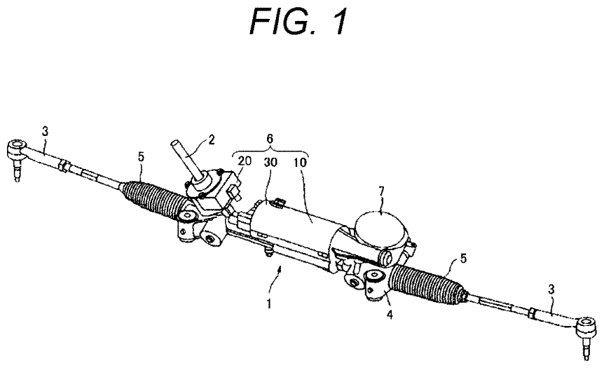

Hereinafter, an embodiment of an electronic control unit according to the present invention will be described with reference to the drawings. The present embodiment will be described by exemplifying a case where the present invention is applied to an electronic control unit of an electric power steering device.

[One Embodiment] First, a configuration of an electric power steering device including an electronic control unit according to one embodiment of the present invention will be described with reference to FIG. 1. FIG. 1 is a perspective view illustrating an electric power steering device including an electronic control unit according to one embodiment of the present invention.

In FIG. 1, an electric power steering device 1 supplements a steering force of a steering wheel (not illustrated) by a rotational driving force of an electric motor 10 when vehicle wheels (not illustrated) are steered via the steering wheel operated by a driver of a vehicle.

For example, the electric power steering device 1 includes: a steering shaft 2 (only a part thereof is illustrated) connected to the steering wheel; a rack (not illustrated) engaged with a pinion (not illustrated) provided at a lower end of the steering shaft 2, covered by a rack housing 4, and elongating in a left-right direction of a vehicle body; and tie rods 3 connected to both ends of the rack, respectively, to steer the wheels in the left-right direction. Rubber boots 5 are provided between the rack housing 4 and the tie rods 3.

The electric power steering device 1 further includes an electric drive device 6 supplementing a steering torque when the steering wheel is operated. For example, the electric drive device 6 includes: an electric motor 10 applying a supplemental steering force to the rack via a gear 7, steering sensors 20 detecting steering angles and steering torques of the steering shaft 2, and an electronic control unit (hereinafter, referred to as ECU) 30 controlling the electric motor 10 based on detection values of the steering sensors 20. The electric motor 10 and the ECU 30 are configured, for example, in an integrally incorporated structure, and the ECU 30 is disposed at an end portion of the electric motor 10 on an opposite side of an output shaft (the gear 7). Note that the steering sensors 20 can be configured separately from the electric drive device 6.

In the electric power steering device 1, when the steering is turned, a turn driving force thereof is transmitted to the left and right tie rods via the steering shaft 2 to steer the left and right wheels. At this time, in the electric drive device 6, the steering sensors 20 detect steering angles and steering torques of the steering shaft 2 as the steering wheel is operated, and the ECU 30 calculates a control amount of the electric motor 10 based on detection values of the steering sensors 20. Based on the control amount of the ECU 30, the electric motor 10 is rotated to drive the steering shaft 2 in the same direction as the operation direction, and the rotation of the electric motor 10 is transmitted to the rack via the gear 7, thereby supplementing the steering torque of the steering wheel.

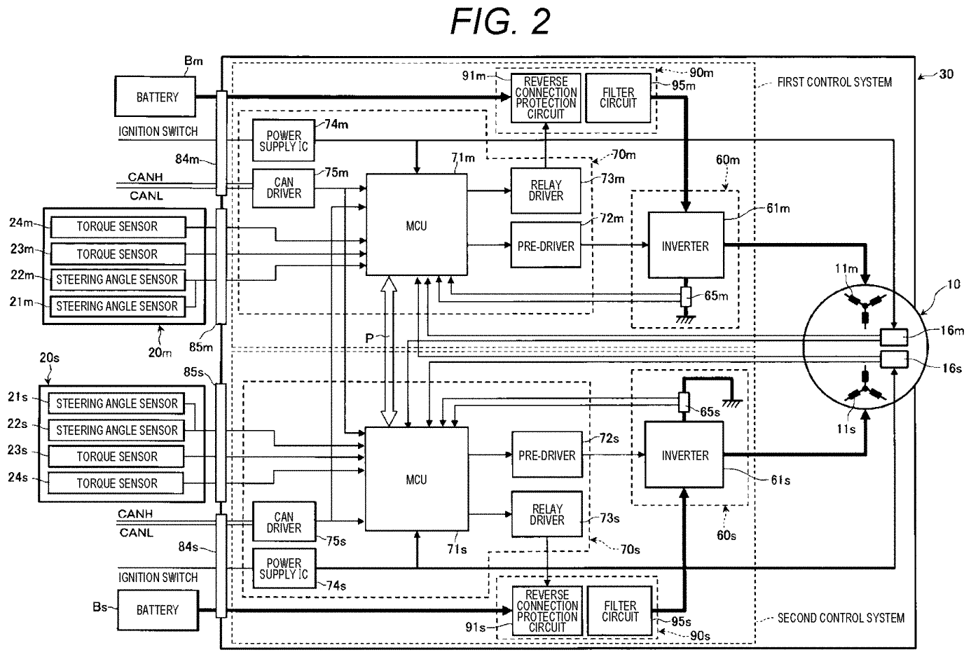

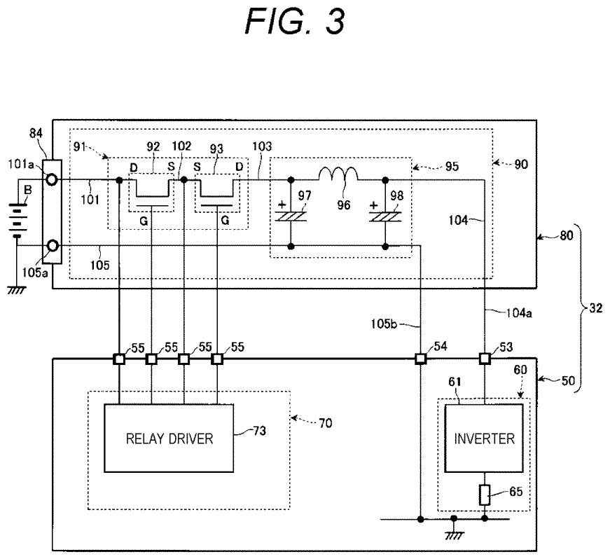

An electric system configuration of an electric drive device including an electronic control unit according to one embodiment of the present invention will be described with reference to FIGS. 2 and 3. FIG. 2 is a block diagram illustrating an electric system configuration of an electric drive device including an electronic control unit according to one embodiment of the present invention. FIG. 3 is a circuit diagram illustrating a configuration of a power supply circuit unit illustrated in FIG. 2. FIG. 3 illustrates only one of two systems illustrated in FIG. 2.

The electric drive device 6 illustrated in FIG. 2 has a configuration in which redundancy is given to the electric motor 10, the ECU 30 controlling the electric motor 10, and various sensors inputting various kinds of information to the ECU 30, so that driving can be continued even if a failure occurs in any type of part.

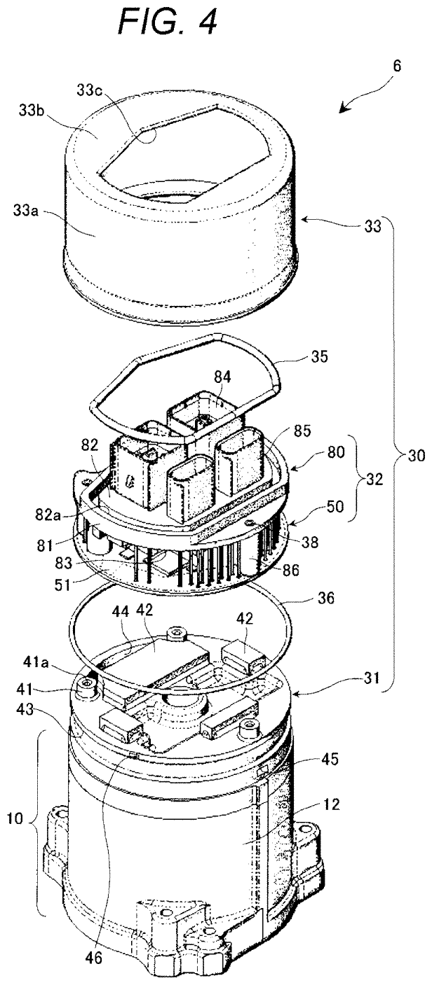

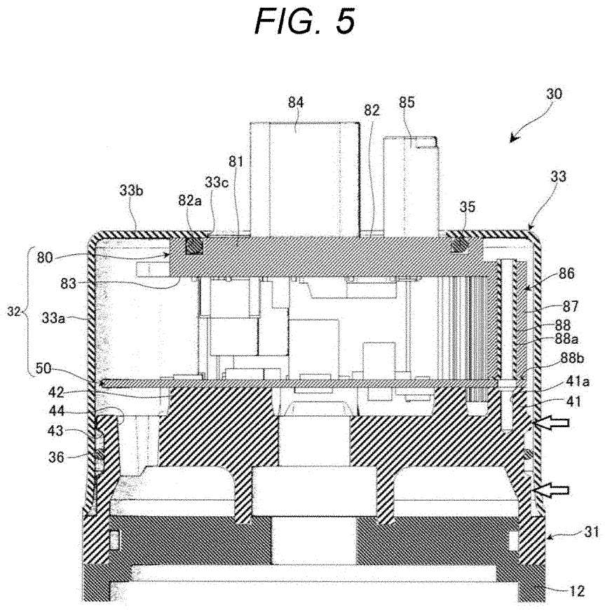

The electric motor 10 is, for example, a three-phase motor driven by three-phase AC power, and includes: one stator (not illustrated) including a first three-phase winding 11m constituted by a U-phase coil, a V-phase coil, and a W-phase coil and a second three-phase winding 11s similarly constituted by a U-phase coil, a V-phase coil, and a W-phase, and one rotor (not illustrated) including an output shaft rotatably disposed on an inner circumferential side of the stator. The electric motor 10 is configured such that one rotor is rotationally driven by three-phase windings of two systems including the first three-phase winding 11m and the second three-phase winding 11s. The stator including the first and second three-phase windings 11m and 11s and the rotor of the electric motor 10 are accommodated in a motor housing 12, which will be described later (see FIGS. 4 and 5 to be described later).

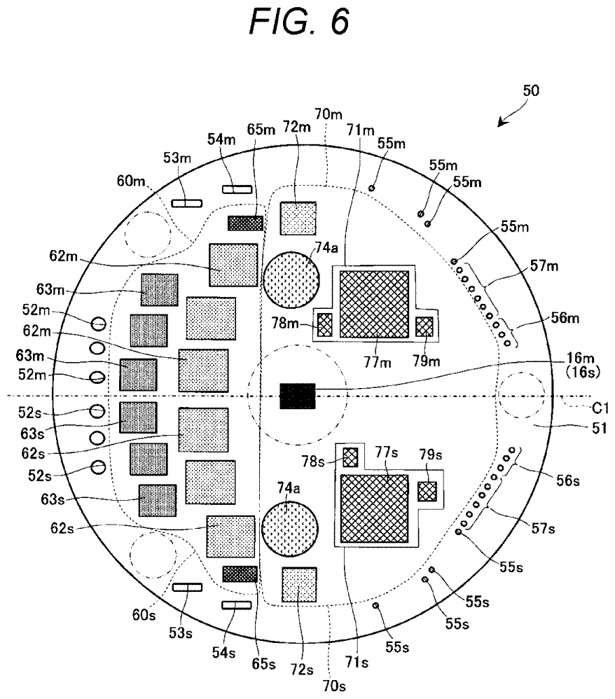

A motor rotation angle, which is a rotation angle of the rotor of the electric motor 10, is detected by rotation angle sensors 16m and 16s. The rotation angle sensors are configured as dual sensors including a main sensor 16m and a sub sensor 16s, and each of the two sensors 16m and 16s is configured to detect a motor rotation angle. Both the main sensor 16m and the sub sensor 16s as rotation angle sensors output detection signals for the motor rotation angles to both dual control systems of the ECU 30, respectively. In the present embodiment, the rotation angle sensors 16m and 16s are mounted on a board 51 of a board module 50 of the ECU 30, which will be described later (see FIG. 6 to be described later).

The ECU 30 controls the driving of the electric motor 10 including two sets of three-phase windings 11m and 11s, and includes redundant systems controlling the respective three-phase windings. That is, an electronic circuit of the ECU 30 includes two systems including a first control system independently controlling the first three-phase winding 11m and a second control system independently controlling the second three-phase winding 11s. The first control system and the second control system have substantially the same electrical configuration. In the following description, m will be added to the end of a reference numeral for a part corresponding to the first control system, and s will be added to the end of a reference numeral for a part corresponding to the second control system. However, m and s may be omitted if necessary.

Electric circuits of the first control system and the second control system of the ECU 30 include power conversion circuit units 60m and 60s controlling the driving of the electric motor 10, control circuit units 70m and 70s controlling the power conversion circuit units 60m and 60s, and power supply circuit units 90m and 90s connected to power supplies (batteries B) to supply power from the power supplies to the power conversion circuit units 60m and 60s and the control circuit units 70m and 70s, respectively.

The power conversion circuit units 60m and 60s include inverter circuits 61m and 61s converting currents supplied from the power supplies from DC currents to three-phase AC currents to supply the converted currents to the three-phase windings 11m and 11s, and current sensors 65m and 65s provided between the inverter circuits 61m and 61s and the ground to each detect a value of a motor current flowing through the electric motor 10. The inverter circuits 61m and 61s include three-phase bridge circuits including high-side switching elements and low-side switching elements (a total of six switching elements 62m or 62s in each of the systems) for supplying the current to the U-phase coil, the V-phase coil, and the W-phase coil of the electric motor 10, respectively, and switching elements 63m and 63s for motor relays capable of cutting off the current to the respective-phase coils (three in total in each of the systems) (see FIG. to be described later). Each switching element is constituted by, for example, an FET. The current sensors 65m and 65s are so-called shunt resistors, each being configured to detect a motor current value based on a potential difference between both ends of the shunt resistor. The current sensors 65m and 65s of the respective systems output motor current value detection signals to MCUs 71m and 71s, which will be described later, of the corresponding systems.

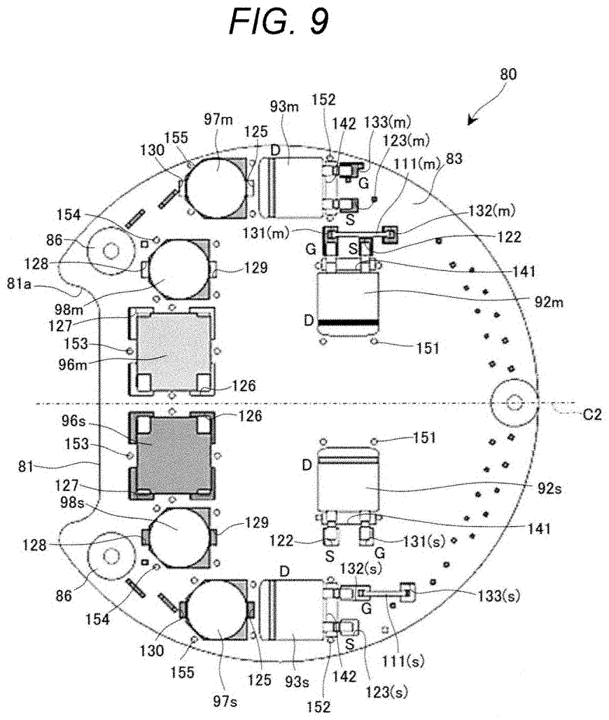

The control circuit units 70m and 70s include MCUs 71m and 71s receiving output signals from the various sensors to perform calculations for assistance control in supplementing a steering torque of the steering wheel, control a motor current, and the like, pre-drivers 72m and 72s that are integrated circuits (ICs) driving the inverter circuits 61m and 61s based on command signals from the MCUs 71m and 71s, and relay drivers 73m and 73s that are integrated circuits (ICs) driving reverse connection protection circuits 91m and 91s, which will be described later, based on command signals from the MCUs 71m and 71s. The MCUs 71m and 71s include microcomputers 77, oscillators 78, memories 79, etc. (see FIG. 9 to be described later). The two MCUs 71m and 71s of the first control system and the second control system perform inter-processor communication P to exchange information required for various types of controls with each other.

In addition, the control circuit units 70m and 70s include power supply ICs 74m and 74s generating power required for driving the ECU 30, and CAN drivers 75m and 75s enabling communication with an external ECU via CAN. When a turn-on signal of an ignition switch is input, the power supply ICs 74m and 74s are activated to appropriately lower power from the batteries B and supply the appropriately lowered power to the MCUs 71m and 71s, the rotation angle sensors, and the steering sensors 20. The CAN is for performing bidirectional communication using two communication lines called CANH and CANL. The CAN drivers 75m and 75s receive, for example, vehicle speed signals and the like via the CAN, and input the vehicle speed signals and the like to the MCUs 71m and 71s. The two communication lines of the CAN and the signal line of the ignition switch can be connected via first connector units 84m and 84s of a connector module 80, which will be described later.

The power supply circuit units 90m and 90s include reverse connection protection circuits 91m and 91s provided between the power supplies (batteries B) and the inverter circuits 61m and 61s, and filter circuits 95m and 95s provided between the reverse connection protection circuits 91m and 91s and the inverter circuits 61m and 61s.

As illustrated in FIG. 3, the reverse connection protection circuit 91 includes a first relay (fail-safe relay) 92 and a second relay (reverse connection protection relay) 93 connected in series to each other between the power supply and the inverter circuit 61. The first relay 92 and the second relay 93, each being constituted by, for example, an FET, form a bidirectional relay by setting source electrodes of the two FETs to the same potential. In a case where the power supply is connected to have a reverse polarity or in a case where a short circuit occurs in the power supply, the reverse connection protection circuit 91 cuts off the current to protect the circuit. Each of the first relay 92 and the second relay 93 of the reverse connection protection circuit 91 is connected to the relay driver 73 of the control circuit unit 70 via a control line, and the driving thereof is controlled by the relay driver 73 based on a command signal from the MCU 71.

The filter circuit 95 includes, for example, a coil 96 disposed between the reverse connection protection circuit 91 and the inverter circuit 61, and a first capacitor 97 and a second capacitor 98 connecting both ends of the coil 96, respectively, to the ground. The filter circuit 95 suppresses emission of noise generated by the operation of the switching element of the power conversion circuit unit 60 to the power supply, and suppresses noise of power flowing from the power supply to the power conversion circuit unit 60.

As illustrated in FIG. 2, the steering sensors 20 include steering angle sensors each detecting a steering angle of the steering wheel, and torque sensors each detecting a steering torque input to the steering wheel. The steering angle sensors are configured as quadruple sensors including first sensors 21m and 21s and second sensors 22m and 22s corresponding to the respective control systems. The steering angle sensors 21m, 21s, 22m, and 22s include, for example, giant magneto-resistance (GMR) elements. The torque sensors are configured as quadruple sensors including first sensors 23m and 23s and second sensors 24m and 24s corresponding to the respective control systems. The torque sensors 23m, 23s, 24m, and 24s include, for example, hall elements.

The first and second sensors 21m, 22m, 21s, and 22s as steering angle sensors corresponding to the respective systems can be electrically connected to the MCUs 71m and 71s, and output steering angle detection signals to the MCUs 71m and 71s. The first and second sensors 23m, 24m, 23s, and 24s as torque sensors corresponding to the respective systems can be electrically connected to the MCUs 71m and 71s, respectively, and output steering torque detection signals to the MCUs 71m and 71s, respectively.

Various electronic components, power supply lines, control lines, and signal lines constituting the electric circuits of the first control system and the second control system described above constitute an electronic component assembly 32, which will be described later.

More specifically, the power conversion circuit units 60m and 60s and the control circuit units 70m and 70s constitute the board module 50, which will be described later, and the power supply circuit units 90m and 90s constitute the connector module 80, which will be described later.

A structure of an electric drive device including an electronic control unit according to one embodiment of the present invention will be described with reference to FIGS. and 5. FIG. 4 is a perspective view illustrating an electric drive device including an electronic control unit according to one embodiment of the present invention in a partially exploded state. FIG. 5 is a longitudinal sectional view illustrating a structure of an electronic control unit according to one embodiment of the present invention.

In FIG. 4, the electric drive device 6 of the electric power steering device 1 is configured such that the electric motor 10 and the ECU 30 have an integrated structure. The electric motor 10 includes a stator (not illustrated) including first and second three-phase windings 11m and 11s (see FIG. 2), a rotor (not illustrated) including an output shaft, and a motor housing 12 accommodating the stator and the rotor. The motor housing 12 is formed of, for example, a metal such as an aluminum alloy.

As illustrated in FIGS. 4 and 5, the ECU 30 includes a mounting base 31 mounted on one side end (an upper side end in FIGS. 4 and 5) of the motor housing 12 in an axial direction, an electronic component assembly 32 fixed to the mounting base 31, and a cover 33 mounted on the mounting base 31 to cover the electronic component assembly 32. In addition, the ECU 30 includes a first seal member 35 sealing a gap between the electronic component assembly 32 and the cover 33, and a second seal member 36 sealing a gap between the mounting base 31 and the cover 33.

The mounting base 31 is formed to have a substantially circular shape when viewed in the axial direction of the motor housing 12 according to the cylindrical shape of the motor housing 12. The mounting base 31 has a plurality of mounting supports 41 for mounting the electronic component assembly 32 thereon. For example, three mounting supports are disposed at equal intervals along an outer circumferential portion of the mounting base 31. Each of the mounting supports 41 has a screw hole 41a.

The mounting base 31 is made of a metal to have a heat sink function to dissipate heat generated from a plurality of electronic components constituting the electronic component assembly 32, and has a plurality of protrusions 42 contacting the electronic component assembly 32. For example, the protrusions 42 are provided at positions corresponding to the arrangement of the electronic components constituting the power conversion circuit units 60m and 60s illustrated in FIG. 2. An annular groove 43 for disposing the second seal member 36 is provided along an outer circumferential surface of the mounting base 31. An insertion hole 44 penetrating toward the electric motor 10 is formed between two mounting supports 41 in the outer circumferential portion of the mounting base 31. End portions of the first and second three-phase windings 11m and 11s (see FIG. 2) of the electric motor 10 are inserted into the insertion hole 44.

A first caulking recess 45 for caulking the cover 33 is formed in the outer circumferential surface of the mounting base 31 at a portion lower than the annular groove 43. A second caulking recess 46 for caulking the cover 33 is formed in the outer circumferential surface of the mounting base 31 at a portion higher than the annular groove 43 and different in a circumferential direction from the first caulking recess 45.

The electronic component assembly 32 realizes the electric circuits of the first control system and the second control system illustrated in FIG. 2, and includes a board module 50 in which various electronic devices are mounted on a board 51, and a connector module 80 that is a connector assembly including two sets of first connector units 84 enabling electrical connection to the power supplies and the like and two sets of second connector units 85 enabling electrical connection to the steering sensors 20 that are external sensors. In the electronic component assembly 32, the board module 50 and the connector module 80 are stacked in this order on the mounting base 31.

The connector module 80 has an annular groove 82a for disposing the first seal member 35 therein. Configurations and structures of the board module 50 and the connector module 80 will be described in detail later.

The cover 33 is formed of, for example, a metal, such as an aluminum alloy or iron, or a resin in the form of a cylinder having a bottom with one side opened. A bottom portion 33b of the cover 33 has an opening 33c for exposing the first connector units 84 and the second connector units 85 of the connector module 80 to the outside. The cover 33 is fixed to the mounting base 31 by caulking an outer circumferential portion of a cylindrical portion 33a at positions corresponding to the first caulking recess 45 and the second caulking recess 46 of the mounting base 31 (see white arrows in FIG. 5) in a state where an inner surface (bottom surface) of the bottom portion 33b presses the first seal member 35 into the annular groove 82a of the connector module 80, such that the outer circumferential portion of the cylindrical portion 33a is pushed into the first caulking recess 45 and the second caulking recess 46.

As a result, the cover 33 can be fixed to the mounting base 31 without using a fastening member. Therefore, it is not necessary to secure a space for placing a fastening member for the cover 33, and it is possible to secure an area for mounting the electronic components of the electronic component assembly 32 accordingly. In addition, the first seal member 35 can seal a gap between a surface of the connector module 80 on a side where the first connector units and the second connector units 85 are placed and the bottom surface of the cover 33, and the second seal member 36 can seal a gap between the outer circumferential surface of the mounting base 31 and an inner circumferential surface of the cylindrical portion 33a of the cover 33.

Next, a structure of a board module constituting an electronic control unit according to one embodiment of the present invention will be described with reference to FIGS. and 6. FIG. 6 is a schematic view illustrating a configuration and arrangement of electronic components of a board module constituting a part of an electronic control unit according to one embodiment of the present invention.

In the board module 50, the power conversion circuit units 60m and 60s and the control circuit units 70m and 70s of the two systems illustrated in FIG. 2 are provided on the same board 51. The board module 50 includes various electronic components constituting the power conversion circuit units 60m and 60s of the two systems mounted on the board 51, and various electronic components constituting the control circuit units 70m and 70s of the two systems mounted on the board 51.

The board 51 is made of, for example, a non-metallic base material such as an epoxy resin base material. The board 51 has first connection portions 52m and 52s for connection to the end portions of the first and second three-phase windings 11m and 11s (see FIG. 2) of the electric motor 10 in an outer circumferential portion of a substantially circular shape on one side in an extending direction of a center line C1. Six first connection portions 52m and 52s connected to the end portions of the respective-phase coils are arranged side by side in a direction orthogonal to the center line C1, while being divided into three first connection portions 52m and three first connection portions 52s with respect to the center line C1 as a boundary. The position of the first connection portions 52m and 52s corresponds to the position of the insertion hole 44 of the mounting base 31. In addition, the board 51 has second connection portions 53m and 53s and third connection portions 54m and 54s, for connection to positive electrode-side connection portions 104a and ground-side connection portions 105b of the power supply lines of the two systems, which will be described later, of the connector module 80 at positions close to an outer circumference thereof in the direction orthogonal to the center line C1 and close to the first connection portions 52m and 52s, respectively. The board 51 has a plurality of fourth connection portions 55m and 55s (four fourth connection portions 55m and four fourth connection portions 55s in FIG. 6) for connection to connection portions 101b, 102a, 106a(s), 107a(m), and 108a of control lines, which will be described later, in the connector module 80. Further, the board 51 has a plurality of fifth connection portions 56m and 56s and sixth connection portions 57m and 57s (three fifth connection portions 56m and three fifth connection portions 56s, and six sixth connection portions 57m and six sixth connection portions 57s in FIG. 6) for connection to connection portions 109b(m, s) and 110b(m, s) of signal lines, which will be described later, in the connector module 80. The fourth connection portions 55m and 55s, the fifth connection portions 56m and 56s, and the sixth connection portions 57m and 57s are arranged side by side opposite to the first connection portions 52m and 52s in the extending direction of the center line C1 on the outer circumferential side. The fifth connection portions 56m and 56s, the sixth connection portions 57m and 57s, and the fourth connection portions 55m and 55s are located to be farther away from the center line C1 in this order.

The various electronic components of the power conversion circuit units 60m and 60s and the control circuit units 70m and 70s of the two systems are disposed closer to an inner circumference than the first connection portions 52m and 52s to the sixth connection portions 57m and 57s. The various electronic components constituting the power conversion circuit unit 60m and the control circuit unit 70m of the first control system are disposed on one side (upper side in FIG. 6) with the center line C1 as a boundary. On the other hand, the various electronic components constituting the power conversion circuit unit 60s and the control circuit unit 70s of the second control system are disposed on the other side (lower side in FIG. 5) with the center line C1 as a boundary. In the respective control systems, the power conversion circuit units 60m and 60s are disposed on one side (left side in FIG. 6) in the extending direction of the center line C1, and the control circuit units 70m and 70s are disposed on the other side in the extending direction of the center line C1 (right side in FIG. 6). By disposing the control circuit units 70m and 70s far away from the power conversion circuit units 60m and 60s generating a large amount of heat, it is possible to suppress the influence of heat on the control circuit units 70m and 70s. The various electronic components of the power conversion circuit unit 60m and the control circuit unit 70m of the first control system and the various electronic components of the power conversion circuit unit 60s and the control circuit unit 70s of the second control system are arranged to be substantially line-symmetric about the center line C1. As a result, the electronic components can be efficiently arranged on one board 51.

Specifically, among the electronic components constituting the power conversion circuit units 60m and 60s of the respective systems, the respective three switching elements 63m and 63s for the motor relays of the inverter circuits 61m and 61s are disposed adjacent to the first connection portions 52m and 52s in the extending direction of the center line C1 while being closer to the center than the first connection portions 52m and 52s, and are arranged side by side in the direction orthogonal to the center line C1. Also, the switching elements 62m and 62s for the three-phase bridge circuits of the inverter circuits 61m and 61s are disposed adjacent to the switching elements 63m and 63s for the motor relays in the extending direction of the center line C1 while being closer to the center than the switching elements 63m and 63s for the motor relays, and are arranged side by side in the direction orthogonal to the center line C1. Here, concerning the switching elements 62m and 62s for the three-phase bridge circuits, two elements including a high-side switching element and a low-side switching element are configured as one package. The current sensors 65m and 65s of the power conversion circuit units 60m and 60s are disposed closer to the outer circumference than the switching elements 62m and 62s for the three-phase bridge circuits in the direction orthogonal to the center line C1.

In addition, among the electronic components constituting the control circuit units 70m and 70s of the respective systems, the microcomputers 77m and 77s, the oscillators 78m and 78s, and the memories 79m and 79s constituting the MCUs 71m and 71s are disposed at positions far away from the switching elements 62m and 62s for the three-phase bridge circuits in the extending direction of the center line C1 and away from the center line C1. The pre-drivers 72m and 72s are disposed closer to the switching elements 62m and 62s for the three-phase bridge circuits than the MCUs 71m and 71s in the extending direction of the center line C1, and closer to the circumference than the MCUs 71m and 71s and the switching elements 62m and 62s for the three-phase bridge circuits. The power supply ICs 74m and 74s are disposed on a surface of the board opposite to the surface on which the MCUs 71m and 71s and the pre-drivers 72m and 72s are mounted. Capacitors 74a for input to the power supply ICs 74m and 74s are mounted on the board 51.

The rotation angle sensors 16m and 16s are mounted at a central portion of the board 51, that is, at a position on an extension line of the output shaft of the electric motor 10. One of the motor rotation angle sensors 16m and 16s of the two systems is disposed on the surface of the board on which the above-described various electronic components are mounted, and the other one is disposed on the surface of the board on which the power supply ICs 74m and 74s are mounted.

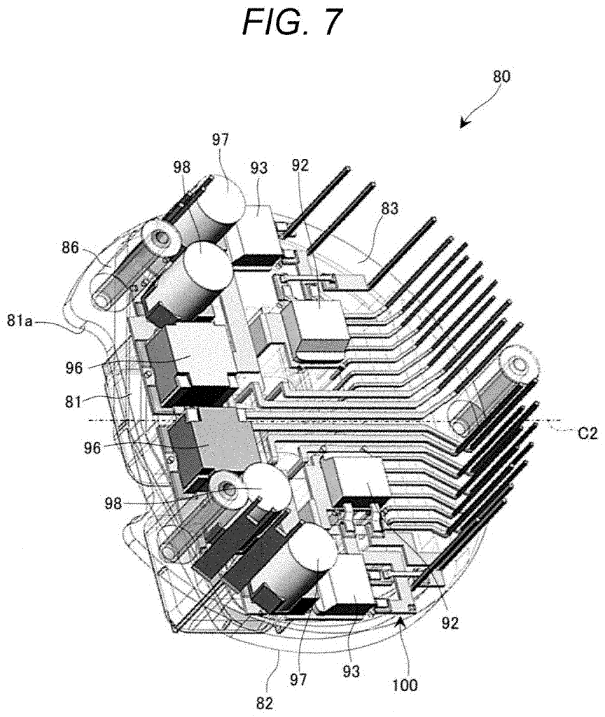

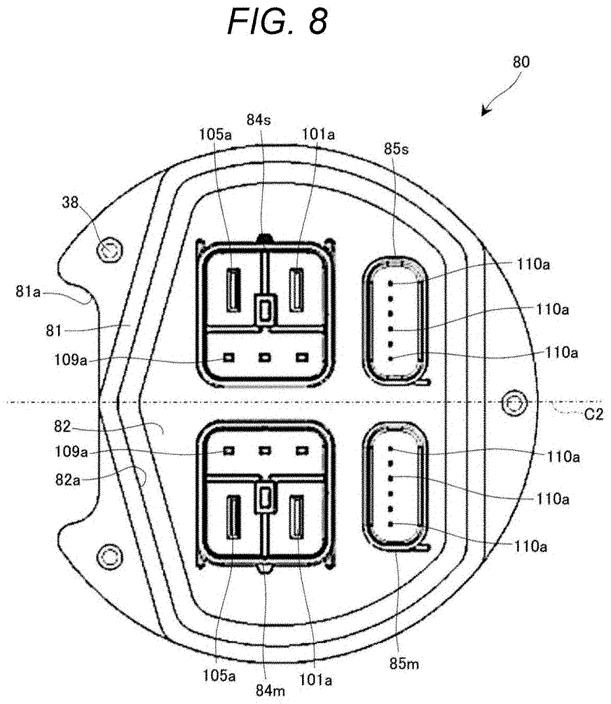

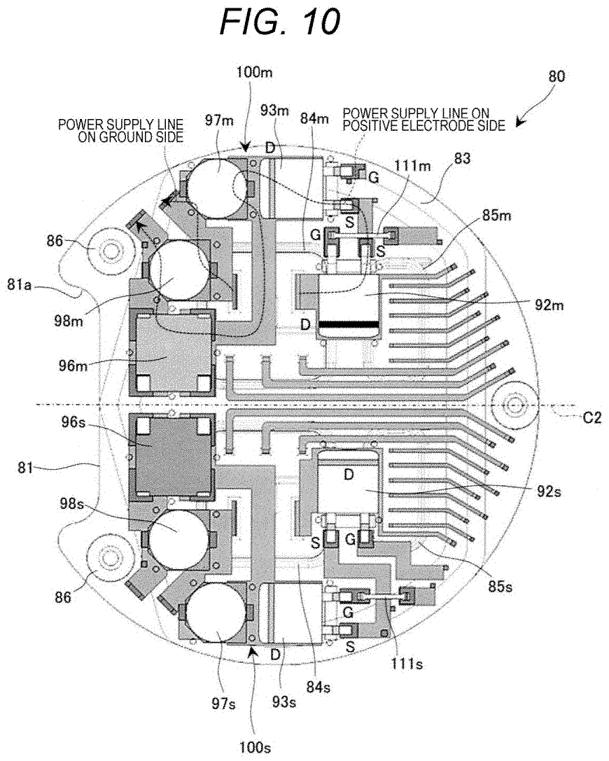

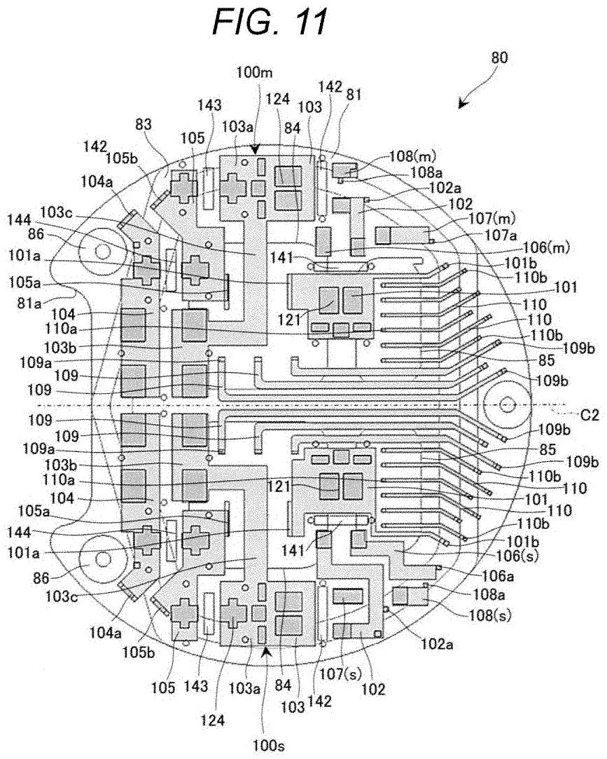

A structure of a connector module of an electronic control unit according to one embodiment of the present invention will be described with reference to FIGS. 2 to 5 and FIGS. 7 to 11. FIG. 7 is a perspective view illustrating a connector module constituting a part of an electronic control unit according to one embodiment of the present invention, in a state where a connector base of the connector module is transparent. FIG. 8 is a plan view of a connector module constituting a part of an electronic control unit according to one embodiment of the present invention when viewed from above connector units. FIG. 9 is a plan view of a connector module constituting a part of an electronic control unit according to one embodiment of the present invention when viewed from a surface on which electronic components are mounted. FIG. 10 is a view illustrating the connector module illustrated in FIG. 9 in a state where a connector base is transparent. FIG. 11 is a transparent view illustrating the arrangement of wiring structures in the connector module illustrated in FIG. 10 in a state where the electronic components are eliminated. In FIG. 11, symbols m and s for distinguishing the first control system and the second control system are attached only when the first control system and the second control system have different configurations.

Briefly, in the connector module 80, two sets of first connector units 84m and 84s and second connector units 85m and 85s corresponding to the first control system and the second control system that are redundant-system electric circuits as illustrated in FIG. 2 are integrally formed therein, and the power supply circuit units 90m and 90s of the two systems including the first control system and the second control system illustrated in FIG. 2 are formed (the various electronic components of the power supply circuit units 90m and 90s illustrated in FIG. 3 are mounted).

Specifically, in FIGS. 4 and 7, the connector module is configured as a connector assembly in which an electrically insulating connector base 81 having a first surface 82 in a planar form and a second surface (back surface) 83 in a planar form opposite to the first surface 82, two sets of first connector units 84 and two sets of second connector units 85 protruding from the first surface of the connector base 81, and wiring structures 100 including a plurality of conductive wirings held in the connector base 81 are integrally formed. Further, in the connector module 80 of the present embodiment, the first relays 92, the second relays 93, the coils 96, the first capacitors 97, and the second capacitors 98 illustrated in FIG. 3, which are electronic components constituting the power supply circuit units 90m and 90s of the two systems, are bonded to the wiring structures 100 in a state where they are placed on the second surface 83 in the planar form of the connector base 81.

The connector base 81 is made of, for example, a synthetic resin, and is formed in a substantially circular shape as illustrated in FIG. 8 when viewed in the axial direction of the electric motor 10 (an insertion direction toward the first connector units 84m and 84s and the second connector units 85m and 85s). The connector base 81 has a notch 81a at a position corresponding to the first connection portions 52m and 52s of the board module 50 (portions connected with the end portions of the three-phase windings of the electric motor 10). That is, the notch 81a is formed to extend in a direction orthogonal to a center line C2 in an outer circumferential portion on one side (left side in FIG. 8) in an extending direction of the center line C2 of the connector base 81 corresponding to the center line C1 (see FIG. 6) of the board module 50. The connector base 81 has an annular groove 82a in the first surface 82 such that the first seal member 35 (see FIG. 4) is disposed therein. The annular groove 82a is formed to surround all of four connectors including two sets of first connector units 84m and 84s and two sets of second connector units 85m and 85s.

The first connector units 84m and 84s of the respective systems are parts having a function as connectors enabling electrical connection to the power supplies and enabling electrical connection to the CAN and the ignition switch, each accommodating two connector terminals 101a and 105a connected to a positive electrode side and a ground side of the power supply and three connector terminals 109a connected to the CAN and the ignition switch, which will be described later. The two connector terminals 101a and 105a for the power supply are, for example, plate-like, and face each other side by side in the extending direction of the center line C2. The three connector terminals 109a are, for example, rod-like, and are positioned closer to the center line C2 than the two connector terminals 101a and 105a while being arranged side by side in the extending direction of the center line C2.

The second connector units 85m and 85s of the respective systems are parts having a function as connectors enabling electrical connection to the steering sensors 20, each accommodating six connector terminals 110a, which will be described later. The six connector terminals 110a are, for example, rod-like, and arranged side by side in the direction orthogonal to the center line C2.

The first connector unit 84m and the second connector unit 85m of the first control system and the first connector unit 84s and the second connector unit 85s of the second control system are arranged to be substantially line-symmetric about the center line C2. The first connector units 84m and 84s are disposed at a substantially central portion of the first surface 82 of the connector base 81 in the extending direction of the center line C2. The second connector units 85m and 85s are adjacent to the first connector units 84m and 84s in the extending direction of the center line C2, and are located opposite to the notch 81a. That is, the second connector units 85m and 85s are disposed at positions corresponding to regions where the control circuit units 70m and 70s of the board module 50 are disposed, rather than regions where the power conversion circuit units 60m and 60s of the board module 50 are disposed. As a result, signal lines connecting the second connector units 85m and 85s and the control circuit units 70m and 70s can be shortened.

As illustrated in FIGS. 9 and 10, first relays 92m and 92s, second relays 93m and 93s, coils 96m and 96s, first capacitors 97m and 97s, and second capacitors 98m and 98s, which are electronic components constituting the power supply circuit units 90m and 90s of the first control system and the second control system, are surface-mounted on the second surface 83 of the connector base 81. These electronic components are, for example, leadless components. In this electronic component mounting method, a space is less required as compared with that in a (through-hole mounting) method in which leads of the electronic components are fixed to the connector base 81 by making holes therein.

The first relay 92m, the second relay 93m, the coil 96m, the first capacitor 97m, and the second capacitor 98m constituting the power supply circuit unit 90m of the first control system, and the first relay 92s, the second relay 93s, the coil 96s, the first capacitor 97s, and the second capacitor 98s constituting the second control system are arranged to be substantially line-symmetric about the center line C2. The various electronic components constituting the power supply circuit units 90m and 90s of the respective systems are arranged such that lengths of wirings of wiring structures 100m and 100s for connecting the electronic components to each other, which will be described later, are as short as possible. This will be described in detail below.

The first relays 92m and 92s are close to the positions of the first connector units 84m and 84s, and are disposed at positions closer to the opposite side of the notch 81a than the central portion in the extending direction of the center line C2. The first relays 92m and 92s are disposed such that sources S and gates G are located closer to the outer circumference than drains D in the direction orthogonal to the center line C2.

The second relays 93m and 93s are disposed in an outer circumferential end portion closer to the outer circumference than the first relays 92m and 92s in the direction orthogonal to the center line C2. The second relays 93m and 93s are disposed such that drains D are located closer to the notch 81a than sources S and gates G in the extending direction of the center line C2. The sources S and the gates G of the second relays 93m and 93s are close to the sources S and the gates G of the first relays 92m and 92s.

The first capacitors 97m and 97s are disposed closer to the notch 81a than the second relays 93m and 93s in the extending direction of the center line C2.

The coils 96m and 96s are disposed in the vicinity of the center line C2 and in the vicinity of the notch 81a (an outer circumferential portion on one side in the extending direction of the center line C2), and are far away from the second relays 93m and 93s and the first capacitors 97m and 97s.

The second capacitors 98m and 98s are adjacent to the coils 96m and 96s and the first capacitors 97m and 97s, and are disposed closer to the outer circumference than the coils 96m and 96s and closer to the inner circumference than the first capacitors 97m and 97s in the direction orthogonal to the center line C2.

As illustrated in FIGS. 10 and 11, the wiring structures 100m and 100s of the two systems including the first control system and the second control system include first wirings 101, second wirings 102, third wirings 103, and fourth wirings 104 constituting power supply lines connected to positive electrode sides of the power supplies in the power supply circuit units illustrated in FIG. 3 for connection to the first relays 92m and 92s, the second relays 93m and 93s, the coils 96m and 96s, the first capacitors 97m and 97s, and the second capacitors 98m and 98s, and fifth wirings 105 constituting power supply lines connected to ground sides of the power supplies in the power supply circuit units illustrated in FIG. 3 for connection to the first capacitors 97m and 97s and the second capacitors 98m and 98s. The wiring structure 100m of the first control system further includes a sixth wiring 106m and a seventh wiring 107m constituting control lines for controlling the first relay 92m, and an eighth wiring 108m constituting a control line for controlling the second relay 93s. On the other hand, the wiring structure 100s of the second control system includes a sixth wiring 106s constituting a control line for controlling the first relay 92s, and a seventh wiring 107s and an eighth wiring 108s constituting control lines for controlling the second relay 93s.

Each of the wiring structures 100m and 100s of the two systems include three ninth wirings 109 constituting signal lines for connecting two signal lines (CANH and CANL) of the CAN and a signal line of the ignition switch illustrated in FIG. 3 to the control circuit unit 70 of the board module 50. In addition, the wiring structures 100m and 100s of the two systems include a plurality of tenth wirings 110 (six wirings in the drawing) constituting signal lines for connecting the steering sensors 20 illustrated in FIG. 3 to the control circuit units 70m and 70s of the board module 50.

The first wirings 101 to the tenth wirings 110 constituting the wiring structures 100m and 100s of the two systems are insert-molded and integrated with the connector base 81.

The wiring structure 100m of the first control system and the wiring structure 100s of the second control system are arranged to be substantially line-symmetric about the center line C2. However, since the sources S and the gates G of the first relays 92m and 92s and the second relays 93m and 93s of the two systems cannot be positioned line-symmetrically, the arrangement is partially different. The first wiring 101 to the fourth wiring 104 constituting the positive electrode-side power supply lines of the respective systems are configured to be as short as possible while securing lengths for connecting the first relays 92m and 92s, the second relays 93m and 93s, the coils 96m and 96s, the first capacitors 97m and 97s, and the second capacitors 98m and 98s. This is intended to reduce resistances of the power supply lines themselves. Further, portions connected to the board module 50 in the positive electrode-side and ground-side power supply lines are disposed close to the outer circumference of the connector base 81. This is intended to prevent the portions connected to the board module 50 in the power supply lines from obstructing the arrangement of the electronic components to be mounted on the connector base 81, and from obstructing the movement of inspection devices when the electronic components mounted on the connector base 81 are inspected.

Briefly, as illustrated in FIG. 10, the positive electrode-side power supply line including the first wiring 101 to the fourth wiring 104 in the present embodiment is configured to extend from the position of the first connector unit 84 to the outer circumferential end portion in the direction orthogonal to the center line C2, turn toward the center line C2 while being close to the notch 81a and extend to the vicinity of the center line C2, and turn toward the outer circumference while being close to the notch 81a and extend to the outer circumferential portion in the direction orthogonal to the center line C2.

This will be described in detail below.

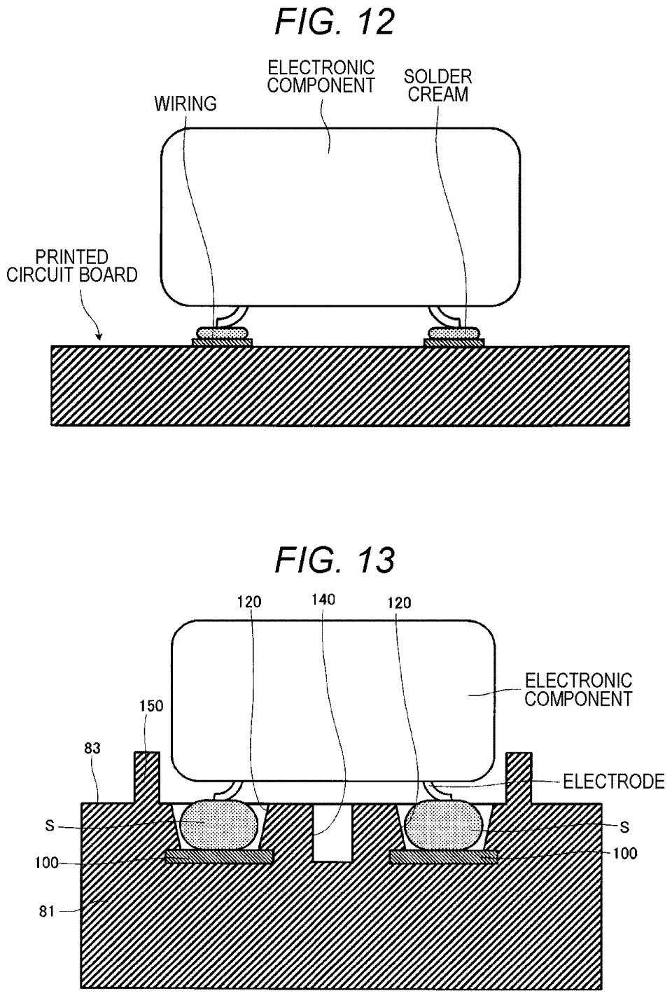

As illustrated in FIGS. 10 and 11, the first wirings 101 are conductive members for connecting the drains D of the first relays 92m and 92s to the positive electrode sides of the power supplies. The first wirings 101 have plate-shaped embedded parts embedded in the connector base 81 and disposed to correspond to the positions of the first connector units 84, and include plate-shaped positive electrode-side connector terminals 101a bent from the embedded parts and protruding from the first surface 82 of the connector base 81 into the first connector units 84 to enable connection to the positive electrode sides of the power supplies, and first control monitoring connection portions 101b in a rod shape bent from the embedded parts and protruding from the second surface 83 of the connector base 81 toward the board module 50 for connection to the control circuit units 70m and 70s of the board module 50 (fourth connection portions 54 in FIG. 6). The embedded parts of the first wirings 101 are bonded to the drains D of the first relays 92m and 92s via solder (see FIG. 13 to be described later) by forming first recesses 121 in the second surface 83 of the connector base 81 such that partial surfaces of the embedded parts are exposed to the outside. The positive electrode-side connector terminal 101a is configured such that a plate-like surface thereof faces the extending direction of the center line C2 to prevent hindrance in the wiring flow of the first wirings 101 to the fourth wirings 104. The first control monitoring connection portions 101b, which serve to connect the drains D of the first relays 92m and 92s to the relay drivers 73m and 73s of the control circuit units 70m and 70s, are positioned at the outer circumferential portion by extending extension portions of the embedded parts to the outer circumferential portion on the opposite side of the notch 81a along a direction parallel to the extending direction of the center line C2.

The second wirings 102 are plate-like conductive members for connecting the sources S of the first relays 92m and 92s and the sources S of the second relays 93m and 93s. The second wirings 102 are disposed closer to the outer circumference than the first wirings 101 in the direction orthogonal to the center line C2, and extends toward the outer circumference in the direction orthogonal to the center line C2. The second wirings 102 are embedded in the connector base 81. The second wirings 102 are bonded to the sources S of the first relays 92m and 92s and the sources S of the second relays 93m and 93s, respectively, via solder (see FIG. 13 to be described later) by forming first recesses 122 and third recesses 123 (see FIG. 9) in the second surface 83 of the connector base 81 such that partial surfaces of the second wirings 102 are exposed to the outside. The second wirings 102 have second control monitoring connection portions 102a in a rod shape protruding from the second surface 83 of the connector base 81 toward the board module 50 for connection to the control circuit units 70m and 70s of the board module 50. The second control monitoring connection portions 102a, which serve to connect the sources S of the second relays 93m and 93s to the relay drivers 73m and 73s, are positioned at the outer circumferential portion of the connector base 81.

The third wirings 103, which are conductive members for connecting the drains D of the second relays 93m and 93s, one ends of the coils 96m and 96s, and the positive electrode sides of the first capacitors 97m and 97s, are embedded in the connector base 81. The third wirings 103 include plate-shaped first embedded parts 103a positioned closer to the notch 81a than the second wirings 102 at outer circumferential end portions in the direction orthogonal to the center line C2, plate-shaped second embedded parts 103b adjacent to center line C2 while being closer to the notch 81a than the ninth wirings 109, and third embedded parts 103c connecting the first embedded part 103a and the second embedded part 103b to each other. The third wirings 103 are bonded to the drains D of the second relays 93m and 93s and the positive electrode sides of the first capacitors 97m and 97s, respectively, via solder (see FIG. 13 to be described later) by forming fourth recesses 124 and fifth recesses 125 (see FIG. 9) in the second surface 83 of the connector base 81 at the positions of the first embedded parts 103a such that partial surfaces of the third wirings 103 are exposed to the outside. In addition, the third wirings 103 are bonded to one end portions of the coils 96m and 96s via solder by forming sixth recesses 126 (see FIG. 9) in the second surface 83 of the connector base 81 at the positions of the second embedded parts 103b such that partial surfaces of the third wirings 103 are exposed to the outside.

The fourth wirings 104 are conductive members for connecting the other ends of the coils 96m and 96s and the positive electrode sides of the second capacitors 98m and 98s. The fourth wirings 104 has plate-shaped embedded parts embedded in the connector base 81 and extending from the vicinity of the center line C2 to outer circumferential end portions of the connector base 81 in the direction orthogonal to the center line C2 at an outer circumferential end portion of the connector base 81 close to the notch 81a in the extending direction of the center line C2, and include plate-shaped positive electrode-side connection portions 104a bent from outer peripheral end portions of the embedded parts and protruding toward the board module 50 from the second surface of the connector base 81 for connection to the power conversion circuit units 60m and 60s of the board module 50. The embedded parts of the fourth wirings 104 are bonded to the other end portions of the coils 96m and 96s via solder by forming seventh recesses 127 (see FIG. 9) in the second surface 83 of the connector base 81 at positions close to the center line C2 such that partial surfaces of the embedded parts are exposed to the outside. The fourth wirings 104 are bonded to the positive electrode sides of the second capacitors 98m and 98s via solder by forming eighth recesses 128 (see FIG. 9) in the second surface 83 of the connector base 81 at positions far away from the center line C2 such that partial surfaces of the fourth wirings 104 are exposed to the outside. The positive electrode-side connection portions 104a, which serve for connection to the inverter circuits 61m and 61s of the power conversion circuit units 60m and 60s, are located on the opposite side of the first control monitoring connection portions 101b and the second control monitoring connection portions 102a in the extending direction of the center line C2.

The fifth wirings 105, which are conductive members for connecting the ground sides of the first capacitors 97m and 97s and the ground sides of the second capacitors 98m and 98s to the ground sides of the power supply lines, are disposed to correspond to the positions of the first connector units 84. Since the fifth wirings 105 are ground-side power supply lines connected only to the first capacitors 97m and 97s and the second capacitors 98m and 98s, among the electronic components constituting the power supply circuit units, they are configured to be as short as possible in order to reduce resistance. Specifically, the fifth wirings 105 have plate-shaped embedded parts embedded in the connector base 81 and expanding from the positions corresponding to the first connector units 84 to the outer circumferential end portions in the direction orthogonal to the center line C2, and include plate-shaped ground-side connector terminals 105a bent from one side end portions of the embedded parts and protruding from the first surface 82 of the connector base 81 into the first connector units 84 to enable connection to the ground sides of the power supplies, and plate-shaped ground-side connector portions 105b bent from the other side end portions of the embedded parts and protruding from the second surface 83 of the connector base 81 toward the board module 50 for connection to the power conversion circuit units 60m and 60s of the board module 50. The embedded parts of the fifth wirings 105 are bonded to the ground sides of the second capacitors 98m and 98s via solder by forming ninth recesses 129 (see FIG. 9) in the second surface 83 of the connector base 81 at positions close to the center line C2 such that partial surfaces of the embedded parts are exposed to the outside. The embedded parts of the fifth wirings 105 are bonded to the ground sides of the first capacitors 97m and 97s via solder by forming tenth recesses 130 (see FIG. 9) in the second surface 83 of the connector base 81 on outer peripheries of the embedded parts such that partial surfaces of the embedded parts are exposed to the outside. The ground side connection portion 105b, which is for connection to the ground side of the board module 50, is adjacent to the positive electrode-side connection portion 104a and close to the outer circumference of the connector base 81.

The sixth wiring 106m and the seventh wiring 107m of the first control system are conductive members for connecting the gate G of the first relay 92m to the relay driver 73m of the control circuit unit 70m. The sixth wiring 106m and the seventh wiring 107m are disposed on both sides with the second wiring 102 interposed therebetween in the extending direction of the center line C2. The sixth wiring 106m is embedded in the connector base 81, and is bonded to the gate G of the first relay 92m and a jumper member (conductive member) 111m via solder by forming an eleventh recess 131m (see FIG. 9) in the second surface 83 of the connector base 81 such that an entire surface of the sixth wiring 106m is exposed to the outside. The seventh wiring 107m has a plate-shaped embedded part embedded in the connector base 81 and located closer to the outer circumference than the sixth wiring 106m in the extending direction of the center line C2, and has a first switching control connection portion 107a in a rod shape bent from the embedded part and protruding from the second surface 83 of the connector base 81 toward the board module 50 for connection to the control circuit unit 70m. The first switching control connection portion 107a, which serves to connect the gate G of the first relay 92m to the relay driver 73m, is disposed adjacent to the first control monitoring connection portion 101b at the outer circumferential end portion of the connector base 81. The embedded part of the seventh wiring 107m is bonded to the jumper member 111m via solder by forming a twelfth recess 132m (see FIG. 9) in the second surface 83 of the connector base 81 such that a partial surface of the embedded part is exposed to the outside. The jumper member 111m is placed on the second surface 83 of the connector base 81, and is bonded to the sixth wiring 106m and the seventh wiring 107m in a state where it is bridged between the sixth wiring 106m and the seventh wiring 107m. By bonding the jumper member 111m to the wiring structure 100s in a state it is placed on the second surface 83 of the connector base 81 similarly to the electronic components, it is possible to make a wiring route of the wiring structure 100s shorter without detouring the wiring route.

The eighth wiring 108m of the first control system is a conductive member for connecting the gate G of the second relay 93m to the relay driver 73m of the control circuit unit 70m. The eighth wiring 108m is disposed closer to the outer circumference than the second wiring 102 in the direction orthogonal to the center line C2. The eighth wiring 108m is embedded in the connector base 81, and is bonded to the gate G of the second relay 93m via solder by forming a thirteenth recess 133m (see FIG. 9) in the second surface 83 of the connector base 81 such that a partial surface of the eighth wiring 108m is exposed to the outside. The eighth wiring 108m has a second switching control connection portion 108a in a rod shape protruding from the second surface 83 of the connector base 81 toward the board module 50 for connection to the control circuit unit 70m. The second switching control connection portion 108a is adjacent to the second control monitoring connection portion 102a at the outer circumferential end portion of the connector base 81.

The sixth wiring 106s of the second control system is a conductive member for connecting the gate G of the first relay 92s to the relay driver 73s of the control circuit unit 70s. The sixth wiring 106s has an embedded part embedded in the connector base 81 and extending toward the outer circumference, and has a first switching control connection portion 106a in a rod shape bent from the embedded part and protruding from the second surface 83 of the connector base 81 toward the board module 50 for connection to the control circuit unit 70s.

The seventh wiring 107s and the eighth wiring 108s of the second control system are conductive members for connecting the gate G of the second relay 93s to the relay driver 73s of the control circuit unit 70s. The seventh wiring 107s and the eighth wiring 108s disposed on both sides with the second wiring 102 interposed therebetween in the extending direction of the center line C2. The seventh wiring 107s is embedded in the connector base 81. The seventh wiring 107s is bonded to the gate G of the second relay 93s and a jumper member (conductive member) 111s via solder by forming a twelfth recess 132s (see FIG. 9) in the second surface 83 of the connector base 81 such that an entire surface of the seventh wiring 107s is exposed to the outside. The eighth wiring 108s has a plate-shaped embedded part embedded in the connector base 81 and disposed closer to the outer circumference than the seventh wiring 107s in the extending direction of the center line C2, and has a second switching control connection portion 108a in a rod shape bent from the embedded part and protruding from the second surface 83 of the connector base 81 toward the board module 50 for connection to the control circuit unit 70s. The embedded part of the eighth wiring 108s is bonded to the jumper member 111s via solder by forming a thirteenth recess 133s (see FIG. 9) in the second surface 83 of the connector base 81 such that a partial surface of the embedded part is exposed to the outside. The jumper member 111s is placed on the second surface 83 of the connector base 81, and is bonded to the seventh wiring 107s and the eighth wiring 108s in a state where it is bridged between the seventh wiring 107s and the eighth wiring 108s. By bonding the jumper member 111s to the wiring structure 100s in a state it is placed on the second surface 83 of the connector base 81 similarly to the electronic components, it is possible to make a wiring route of the wiring structure 100s shorter without detouring the wiring route.

The plate-shaped embedded parts of the first wirings 101 to the eighth wirings 108m and 108s are disposed at the same depth from the second surface 83 of the connector base 81. That is, the plurality of first wirings 101 to eighth wirings 108m and 108s embedded in the connector base 81 are formed in a single-layer structure, rather than in a multi-layer structure.

The plurality of ninth wirings 109 have a plurality of (three) rod-shaped connector-side terminals 109a protruding from the first surface 82 of the connector base 81 into the first connector unit 84 to enable connection to the (two) communication lines (CANH and CANL) of the CAN and the (one) signal line of the ignition switch, and rod-shaped board-side connection portions 109b in the same number protruding from the second surface 83 of the connector base 81 toward the board module 50 for connection to the control circuit unit 70 of the board module 50, while the embedded parts embedded in the connector base 81 extend from the connector-side terminals 109a to the board-side connection portions 109b. The three connector-side terminals 109a of the ninth wirings 109 are located closer to the center line C2 than the positive electrode-side connector terminal 101a of the first wiring 101 and the ground-side connector terminal 105a of the fifth wiring 105, and are arranged side by side in the direction parallel to the extending direction of the center line C2. The three board-side connection portions 109b of the ninth wirings 109 are arranged side by side along the outer circumferential portion on the opposite side of the notch 81a in the vicinity of the center line C2. The three embedded parts of the ninth wirings 109 extend along the extending direction of the center line C2 by shifting a direction in which connector-side portions approach the center line C2 in the direction orthogonal to the center line C2. As a result, the ninth wirings 109 can be connected to the control circuit units 70 of the board module 50 without obstructing the arrangement of the first wirings 101 to the eighth wirings 108m and 108s.

The plurality of tenth wirings 110 have a plurality of rod-shaped connector-side terminals 110a (six terminals in the drawing) protruding from the first surface 82 of the connector base 81 into the second connector units 85 to enable connection to the signal lines of the steering sensors 20, and rod-shaped board-side connection portions 110b in the same number protruding from the second surface 83 of the connector base 81 toward the board module 50 for connection to the control circuit units 70 of the board module 50, while the embedded parts embedded in the connector base 81 extend from the connector-side terminals 110a to the board-side connection portions 110b. The six connector-side terminals 110a of the tenth wirings 110 are arranged side by side in the direction orthogonal to the center line C2. The six board-side connection portions 110b of the tenth wirings 110 are arranged side by side along the outer circumferential portion on the opposite side of the notch 81a The six embedded parts of the ninth wirings 109 are arranged side by side to be closer to the outer circumference than the three embedded parts of the ninth wirings 109 in the direction orthogonal to the center line C2, and extend along the extending direction of the center line C2. As a result, the tenth wirings 110 can be connected to the control circuit units 70 of the board module 50 without obstructing the arrangement of the first wirings 101 to the ninth wirings 109.

A groove 140 (see FIG. 13 to be described later) is formed in the second surface 83 of the base between recesses through which the wirings having different potentials are exposed, among the plurality of recesses 121 to 133, to separate the recesses from each other. This will be described in detail below.

As illustrated in FIGS. 9 and 11, a first groove 141 extending in the extending direction of the center line C2 is provided between the first recess 121, the first recess 122, and the eleventh recess 131 on the second surface 83 of the connector base 81 to separate the first recess 121, the first recess 122, and the eleventh recess 131 from each other. A first groove 142 extending in the direction orthogonal to the center line C2 is provided between the fourth recess 124, the third recess 123, and the thirteenth recess 133 on the second surface 83 of the connector base 81 to separate the fourth recess 124, the third recess 123, and the thirteenth recess 133 from each other. A third groove 143 extending in the direction orthogonal to the center line C2 is provided between the fifth recess 125 and the tenth recess 130 on the second surface 83 of the connector base 81 to separate the fifth recess 125 and the tenth recess 130 from each other. A fourth groove 144 extending in the direction orthogonal to the center line C2 is provided between the eighth recess 128 and the ninth recess 129 on the second surface 83 of the connector base 81 to separate the eighth recess 128 and the ninth recess 129 from each other. The first groove 141 to fourth groove 144 prevent entry of melted solder leaking from each recess into adjacent recesses.

A plurality of protrusions 150 are provided on the second surface 83 of the connector base 81 around locations where various electronic components constituting the power supply circuit units 90m and 90s of the first control system and the second control system are placed (see FIG. 13 to be described later).

The plurality of protrusions 150 restrict the movement of the various electronic components when the various electronic components are bonded to the wiring structures by melted solder. This will be described in detail below.

As illustrated in FIG. 9, a plurality of first protrusions 151 restricting the positional displacement (movement) of the first relays 92m and 92s are provided on the second surface 83 of the connector base 81 in the vicinity of outer peripheries of the first relays 92m and 92s at mounting positions thereof (in the vicinity of the four corners of the rectangular parallelepiped package in FIG. 9). A plurality of second protrusions 152 restricting the positional displacement (movement) of the second relays 93m and 93s are provided in the vicinity of outer peripheries of the second relays 93m and 93s at mounting positions thereof (in the vicinity of the four corners of the rectangular parallelepiped package in FIG. 9). A plurality of third protrusions 153 restricting the positional displacement (movement) of the coils 96m and 96s are provided in the vicinity of outer peripheries of the coils 96m and 96s at mounting positions thereof (in the vicinity of the four corners of the rectangular parallelepiped package in FIG. 9). A plurality of fourth protrusions restricting the positional displacement (movement) of the first capacitors 97m and 97s are provided in the vicinity of outer peripheries of the first capacitors 97m and 97s at mounting positions thereof. A plurality of fifth protrusions 151 restricting the positional displacement (movement) of the first capacitors 97m and 97s are provided in the vicinity of outer peripheries of the second capacitors 98m and 98s at mounting positions thereof.

As illustrated in FIGS. 5 and 7, a plurality of mounting support columns 86 for stacking and mounting the connector module 80 on the board module 50 is erected on the second surface 83 of the connector base 81. Each of the mounting support columns 86 is disposed at a position corresponding to the mounting support 41 of the mounting base 31. For example, three mounting support columns 86 are provided at equal intervals along the outer circumferential portion of the connector base 81. As illustrated in FIG. 5, each of the mounting support columns 86 includes a cylindrical support main body 87 integrated with the connector base 81 and a metal bush 88 integrally molded inside the support main body 87. The bush 88 has a cylindrical portion 88a located on an inner circumferential side of the support main body 87, and an annular flange portion 88b protruding outward from a distal end of the cylindrical portion 88a in a radial direction of the cylindrical portion 88a to cover a distal end surface of the support main body 87.

The connector module 80 is disposed such that the second surface 83 (the surface on which the electronic components are mounted) of the connector base 81 faces the board module 50. As illustrated in FIGS. 4 and 5, the connector module 80 is fixed to the mounting support 41 of the mounting base 31 by screwing a mounting screw 38, through which the cylindrical portion 88a of the bush 88 is inserted, into the screw hole 41a of the mounting support 41 of the mounting base 31 in a state where the connector module 80 is placed on the board module 50. At this time, the flange portion 88b of the bush 88 abuts on (surface-contacts) the surface of the board 51 of the board module 50 to exhibit a function as a washer, thereby preventing the board 51 of the board module 50 from being damaged. In a method for fixing the connector module 80 to the mounting base 31 according to the present embodiment, the board module 50 is fixed by sandwiching the board 51 between the mounting base 31 and the connector module 80. Therefore, a fastening member for mounting the board module 50 on the mounting base 31 is not necessary, a space for mounting the fastening member can be omitted accordingly, and a space for mounting the electronic components on the board 51 of the board module 50 can be secured accordingly.

Next, a method for mounting an electronic component on a connector module constituting an electronic control unit according to one embodiment of the present invention will be described in comparison with a general method for mounting an electronic component on a board.

First, a general method of surface-mounting an electronic component on a board will be described with reference to FIG. 12. FIG. 12 is an explanatory diagram illustrating an example of a general method of surface-mounting an electronic component on a board.

First, a printed circuit board is covered with a metal mask, and solder cream is printed on the printed circuit board using a printer. At this time, a thickness of the solder cream is about 150 μm. Next, an electronic component is placed on the printed circuit board on which the solder cream is printed using a machine called a chip mounter. Thereafter, the printed circuit board on which the electronic component is placed is introduced into a reflow furnace to heat and melt the solder, thereby bonding the electronic component to the printed circuit board.

Next, a method of mounting an electronic component on a connector module in which a wiring structure is insert-molded in a connector base according to the present embodiment will be described with reference to FIG. 13. FIG. 13 is a schematic diagram illustrating a method of mounting an electronic component on a connector module constituting a part of an electronic control unit according to one embodiment of the present invention.

The wiring structure 100 insert-molded in the connector base 81 is exposed toward the second surface 83 through the recess 120 (recesses 121 to 133 illustrated in FIG. 9) formed in the second surface 83 of the connector base 81. The recess 120 has a depth of, for example, 600 μm. This is for securing a holding force for holding the insert-molded wiring structure 100 in the connector base 81.

Since a surface of the wiring structure 100 correspond to a bottom surface of the recess 120, the recess 120 is filled with solder cream S up to a position where the electronic component can be supported. That is, the solder cream S is filled in the recess 120 at a height of about 600 μm. This is about four times the thickness of solder cream in the general board surface mounting. In this case, it is difficult to print the solder cream using the metal mask.

Next, an electronic component is placed on the recess 120 filled with the solder cream S in the second surface 83 of the connector base 81 using a machine called a chip mounter. Thereafter, the connector base 81 on which the electronic component is placed is introduced into a reflow furnace to heat and melt the solder paste S, thereby bonding electrodes of the electronic component to the wiring structure 100. These steps are similar to those in the general method of surface-mounting the electronic component.

Meanwhile, there is concern that when the solder cream S is melted by being heated in the reflow furnace, the solder cream S filled in the recess 120 to have a height of about 600 μm may leak from the recess 120. However, even if the solder paste S leaks from any of the recesses 120, the leaking melted solder flows into the groove 140 provided between the recesses 120, so that the leaking melted solder can be prevented from entering another one of the recesses 120, thereby preventing the wiring structures 100 from being short-circuited. When the solder cream is melted, the electronic component placed on the second surface 83 of the connector base 81 may be displaced. However, the protrusions 150 protruding from the second surface 83 of the connector base 81 can suppress positional displacement (movement) of the electronic component.

An electronic control unit according to one embodiment of the present invention described above includes: a board module 50 in which an electric circuit is formed on a board 51; and a connector module 80 in which a conductive wiring structure 100 is held in a connector base (base) 81 having a second surface (plane surface) 83 to enable electric connection between the electric circuit of the board module 50 and an external device via the wiring structure 100. The wiring structure 100 of the connector module 80 has portions exposed toward the second surface (plane surface) 83 of the connector base (base) 81, and the connector module 80 has electronic components 92, 93, 96, 97, and 98 bonded to the wiring structure 100 in a state where they are placed on the second surface (plane surface) 83 of the connector base (base) 81.

According to this configuration, since the electronic components 92, 93, 96, 97, and 98 are bonded to the wiring structure 100 in a state where the electronic components 92, 93, 96, 97, and 98 are placed on the second surface (plane surface) 83 of the connector base (base) 81 of the connector module 80, only spaces for placing the electronic components 92, 93, 96, 97, and 98 are required at the time of bonding the electronic components 92, 93, 96, 97, and 98, and it is not necessary to secure extra spaces for securing bonding portions between the electronic components 92, 93, 96, 97, and 98 and the wiring structure 100. Therefore, the ECU 30 can be downsized.

In the electronic control unit according to the present embodiment, the wiring structure 100 includes embedded parts embedded in the connector base (base) 81, and the embedded parts of the wiring structure 100 are configured such that only portions bonded to the electronic components 92, 93, 96, 97, and 98 are exposed toward the second surface (plane surface) 83 of the connector base (base) 81. According to this configuration, the connector base (base) 81 can reliably hold the wiring structure 100.

In the electronic control unit according to the present embodiment, the electronic components 92, 93, 96, 97, and 98 are configured as leadless components. According to this configuration, since the electronic components 92, 93, 96, 97, and 98 have no lead length, they can be bonded to the wiring structure 100 without having to secure extra spaces, thereby downsizing the ECU 30.

In the electronic control unit according to the present embodiment, the electronic components 92, 93, 96, 97, and 98 are bonded to the wiring structure 100 via solder S. According to this configuration, as a method of bonding the electronic components 92, 93, 96, 97, and 98 to the wiring structure 100 held in a state where it is exposed toward the second surface (plane surface) 83 of the connector base (base) 81, a method similar to surface-mounting of electronic components on a printed circuit board can be adopted.

In the electronic control unit according to the present embodiment, the connector base (base) 81 has a plurality of protrusions 150 (151 to 154) protruding from the second surface (plane surface) 83 around positions at which the electronic components 92, 93, 96, 97, and 98 are placed on the second surface (plane surface) 83 to restrict the movement of the electronic components 92, 93, 96, 97, and 98. According to this configuration, at the time of bonding the electronic components 92, 93, 96, 97, and 98 via metal cream such as solder, the movement of the electronic components 92, 93, 96, 97, and 98 can be restricted when the metal cream is melted. In the electronic control unit according to the present embodiment, the wiring structure 100 includes a plurality of wirings 101 to 110, the plurality of wirings 101 to 110 include respective embedded parts embedded in the base, the connector base (base) 81 has a plurality of recesses 120 (121 to 133) exposing the embedded parts of the plurality of wirings 101 to 110 toward the second surface (plane surface) 83, and the connector base (base) 81 has a groove 140 (141 to 144) between recesses through which the wirings 101 to 110 having different potentials are exposed among the plurality of recesses 120 (121 to 133). According to this configuration, when the recesses 120 (121 to 133) are filled with metal cream such as solder to bond the electronic components 92, 93, 96, 97, and 98 to the wiring structure 100, even if the melted metal cream leaks from any of the recesses 120, the melted metal cream flows into the groove 140, so that the metal cream leaking from the recess 120 can be prevented from entering another one of the recesses 120, thereby preventing the wiring structure 100 from being short-circuited.

In the electronic control unit according to the present embodiment, the wiring structure 100 includes embedded parts embedded in the connector base (base) 81, and the embedded parts of the wiring structure 100 are disposed at positions of the same depth from the second surface (plane surface) 83 of the connector base (base) 81 in a single-layer structure. According to this configuration, the electronic components 92, 93, 96, 97, and 98 can be easily placed on the second surface (plane surface) 83 of the connector base (base) 81.

In the electronic control unit according to the present embodiment, the connector module 80 is disposed such that the second surface (plane surface) 83 of the connector base (base) 81 faces the board module 50. According to this configuration, the board module 50 and the connector module 80 can be compactly accommodated.

In the electronic control unit according to the present embodiment, the connector module 80 enables electrical connection to a power supply, the board module 50 is provided with a power conversion circuit unit 60 and a control circuit unit 70 on the board 51, the power conversion circuit unit 60 converting power supplied from the power supply via the connector module 80 and the control circuit unit 70 controlling driving of the power conversion circuit unit 60, the power conversion circuit unit 60 is disposed on one side of the board 51, and the control circuit unit 70 is disposed on the other side of the board 51.

According to this configuration, since the power conversion circuit unit 60 and the control circuit unit 70 are provided on the same board 51, it is possible to reduce the size in comparison with a configuration in which the power conversion circuit unit and the control circuit unit are arranged on different boards.

In the electronic control unit according to the present embodiment, the connector module 80 enables electrical connection to a power supply, the board module 50 is provided with a power conversion circuit unit 60 and a control circuit unit 70 on the board 51, the power conversion circuit unit 60 converting power supplied from the power supply via the connector module 80 and the control circuit unit 70 controlling driving of the power conversion circuit unit 60, and the electronic components include switching elements 92 and 93 that cut off a current in a case where the power supply is connected to have a reverse polarity or in a case where a short circuit occurs in the power supply. According to this configuration, a power supply line connecting the power supply and the power conversion circuit unit 60 can be efficiently disposed.

In the electronic control unit according to the present embodiment, the wiring structure 100 includes control wirings 106, 107, and 108 functioning as control lines for controlling the switching elements, the control wirings 106, 107, and 108 have connection portions 106a, 107a, and 108a protruding from the connector base (base) 81 toward the board module 50 for connection to the control circuit unit 70 of the board module 50, and the connection portions 106a, 107a, and 108a of the control wirings 106, 107, and 108 are located at an outer circumferential portion of the connector base (base) 81.

According to this configuration, the connection portions 106a, 107a, and 108a can be connected to the board module 50 without obstructing the arrangement of the electronic components.

In the electronic control unit according to the present embodiment, the electronic components further include filter elements 96, 97, and 98 constituting a filter circuit that suppresses noise of power flowing to the power conversion circuit unit, and the filter elements 96, 97, and 98 are disposed closer to the power conversion circuit unit 60 than the switching elements 92 and 93. According to this configuration, according to this configuration, a power supply line connecting the power supply and the power conversion circuit unit 60 can be efficiently disposed.

In the electronic control unit according to the present embodiment, the power conversion circuit unit 60 of the board module 50 converts DC power supplied from the power supply into AC power, and the board module 50 supplies the AC power converted by the power conversion circuit unit 60 to the outside without passing through another board module other than the board module 50. According to this configuration, when AC power is supplied from the power conversion circuit unit 60 to the outside, other board modules are unnecessary, and accordingly, downsizing can be achieved.

The electronic control unit according to the present embodiment further includes a mounting base 31 on which the board module 50 and the connector module 80 are mounted, the board module 50 and the connector module 80 are stacked on the mounting base 31 in this order, and the board module 50 is fixed by sandwiching the board 51 between the mounting base 31 and the connector module 80. According to this configuration, it is not necessary to mount the board module 50 and the connector module 80 on separate mounting bases 31, and the number of fastening members can be reduced accordingly. As such a fastening member is not necessary, the board module 50 can secure a space for mounting electronic components, thereby efficiently arranging the electronic components.

In the electronic control unit according to the present embodiment, the mounting base 31 has a plurality of mounting supports 41 supporting the board module 50 and the connector module 80, the connector module 80 has a plurality of mounting support columns 86 erected at positions corresponding to the plurality of mounting supports 41 of the mounting base 31, respectively, each of the plurality of mounting support columns 86 includes a cylindrical support main body 87 integrated with the connector base (base) 81 and a metal bush 88 integrally molded inside the support main body 87, the bush 88 has a cylindrical portion 88a located on an inner circumferential side of the support main body 87 and an annular flange portion 88b protruding from a distal end of the cylindrical portion 88a toward an outer circumference, and the flange portion 88b of the bush 88 abuts on the board 51 of the board module 50. According to this configuration, the flange portion 88b of the bush 88 surface-contacts the surface of the board 51 of the board module 50 to exhibit a function as a washer, thereby preventing the board 51 of the board module 50 from being damaged.

In the electronic control unit according to the present embodiment, the wiring structure 100 includes a plurality of wirings 101 to 110, the connector module 80 further includes a conductive jumper member 111 bonded to the wiring structure 100 in a state where it is placed on the second surface (plane surface) 83 of the connector base (base) 81, and the jumper member 111 is bonded to two wirings 106, 107, and 108, among the plurality of wirings 101 to 110 of the wiring structure 100, in a state where it is bridged between the two wirings 106, 107, and 108. According to this configuration, the two wirings 106, 107, and 108 are bonded to each other with the jumper member 111 bridged therebetween, a short line can be constructed without detouring a wiring route of the wiring structure 100.

In the electronic control unit according to the present embodiment, the connector module 80 includes connector units 84 and 85 protruding from a first surface 82 opposite to the second surface (plane surface) 83. The electronic control unit further includes: a cover 33 in a form of a cylinder having a bottom covering the board module 50 and the connector module 80 and mounted around an outer circumferential portion of the mounting base 31 in a state where the connector units 84 and 85 of the connector module 80 are exposed to the outside via an opening 33a; a first seal member 35 sealing a gap between the first surface 82 of the connector module 80 and a bottom surface of the cover 33; and a second seal member 36 sealing a gap between an outer circumferential surface of the mounting base 31 and an inner surface of an outer circumferential portion of the cover 33. The cover 33 is fixed by caulking the outer circumferential portion of the cover 33, in a state where the bottom surface of the cover 33 presses the first seal member 35 against the connector module 80, such that the outer circumferential portion of the cover 33 is pressed against the outer circumferential surface of the mounting base 31. According to this configuration, the cover 33 can be fixed to the mounting base 31 in a state where the functions of the first seal member 35 and the second seal member 36 are exhibited without using a fastening member. As such a fastening member for fixing the cover 33 is not necessary, the board module 50 and the connector module 80 can secure a space for mounting electronic components, thereby efficiently arranging the electronic components.

[Other Embodiments] In the embodiment described above, an example in which the electronic control unit of the present invention is applied to an electric power steering device has been described. However, the present invention can be applied to any electronic control unit as long as the electronic control unit includes a board module on which an electric circuit is formed, a board module in which an electric circuit is formed on a board, and a connector module holding a wiring structure.

In addition, the present invention is not limited to the above-described embodiment, and includes various modifications. The above-described embodiment has been described in detail in order to explain the present invention in an easy-to-understand manner, and is not necessarily limited to having all the configurations described above. Some of the configurations of one embodiment may be replaced with configurations of another embodiment, and configurations of one embodiment may be added to configurations of another embodiment. In addition, other configurations may be added to some of the configurations of each embodiment, some of the configurations of each embodiment may be deleted, or some of the configurations of each embodiment may be replaced with other configurations.

For example, in the above-described embodiment, the electronic control unit 30 including a two-system electric circuit has been described as an example. However, the present invention is also applicable to an electronic control unit including a one-system electric circuit.

In addition, in the above-described embodiment, it has been described as an example that only portions bonded to the electronic components 92, 93, 96, 97, and 98 in the embedded parts of the wiring structure 100 embedded in the connector base (base) 81 of the connector module 80 are exposed toward the second surface (plane surface) 83 of the connector base (base) 81. However, the embedded parts of the wiring structure 100 may be configured to entirely expose surfaces thereof facing the second surface (plane surface) 83 of the connector base (base) 81. Even in this case, only spaces for placing the electronic components 92, 93, 96, 97, and 98 are required at the time of bonding the electronic components 92, 93, 96, 97, and 98, and it is not necessary to secure extra spaces for securing bonding portions between the electronic components 92, 93, 96, 97, and 98 and the wiring structure 100. Therefore, downsizing can be achieved.

### OTHER EMBODIMENTS

In the embodiment described above, an example in which the electronic control unit of the present invention is applied to an electric power steering device has been described. However, the present invention can be applied to any electronic control unit as long as the electronic control unit includes a board module on which an electric circuit is formed, a board module in which an electric circuit is formed on a board, and a connector module holding a wiring structure.

In addition, the present invention is not limited to the above-described embodiment, and includes various modifications. The above-described embodiment has been described in detail in order to explain the present invention in an easy-to-understand manner, and is not necessarily limited to having all the configurations described above. Some of the configurations of one embodiment may be replaced with configurations of another embodiment, and configurations of one embodiment may be added to configurations of another embodiment. In addition, other configurations may be added to some of the configurations of each embodiment, some of the configurations of each embodiment may be deleted, or some of the configurations of each embodiment may be replaced with other configurations.

For example, in the above-described embodiment, the electronic control unit 30 including a two-system electric circuit has been described as an example. However, the present invention is also applicable to an electronic control unit including a one-system electric circuit.

In addition, in the above-described embodiment, it has been described as an example that only portions bonded to the electronic components 92, 93, 96, 97, and 98 in the embedded parts of the wiring structure 100 embedded in the connector base (base) 81 of the connector module 80 are exposed toward the second surface (plane surface) 83 of the connector base (base) 81. However, the embedded parts of the wiring structure 100 may be configured to entirely expose surfaces thereof facing the second surface (plane surface) 83 of the connector base (base) 81. Even in this case, only spaces for placing the electronic components 92, 93, 96, 97, and 98 are required at the time of bonding the electronic components 92, 93, 96, 97, and 98, and it is not necessary to secure extra spaces for securing bonding portions between the electronic components 92, 93, 96, 97, and 98 and the wiring structure 100. Therefore, downsizing can be achieved.

### REFERENCE SIGNS LIST

30 electronic control unit
31 mounting base
33 cover
35 first seal member
41 mounting support
50 board module
51 board
60 power conversion circuit unit
70 control circuit unit
80 connector module
81 connector base (base)
82 first surface (surface)
83 second surface (plane surface)
84, 85 connector unit
86 mounting support column
87 support main body
88 bush
88a cylindrical portion
88b flange portion
92 first relay (electronic component)
93 second relay (electronic component)
95 coil (electronic component)
96 first capacitor (electronic component)
98 second capacitor
100 wiring structure
101 to 110 wiring
106, 107, 108 wiring (control wiring)
106a, 107a, 108a connection portion
111 jumper member
150 (151 to 154) protrusion
120 (121 to 133) recess

1. An electronic control unit, comprising:
a board module in which an electric circuit is formed on a board; and
a connector module in which a conductive wiring structure is held in a base having a plane surface to enable electric connection between the electric circuit of the board module and an external device via the wiring structure,
wherein the wiring structure of the connector module has portions exposed toward the plane surface of the base, and
the connector module has electronic components bonded to the wiring structure in a state where the electronic components are placed on the plane surface of the base.

2. The electronic control unit according to claim 1, wherein the wiring structure includes embedded parts embedded in the base, and
the embedded parts of the wiring structure are configured such that only portions bonded to the electronic components are exposed toward the plane surface of the base.

3. The electronic control unit according to claim 1, wherein the wiring structure includes embedded parts embedded in the base, and
the embedded parts of the wiring structure are configured to entirely expose surfaces thereof facing the plane surface of the base.

4. The electronic control unit according to claim 1, wherein
the electronic components are configured as leadless components.

5. The electronic control unit according to claim 1, wherein the electronic components are bonded to the wiring structure via solder.

6. The electronic control unit according to claim 1, wherein the base has a plurality of protrusions protruding from the plane surface around positions at which the electronic components are placed on the plane surface to restrict movement of the electronic components.

7. The electronic control unit according to claim 1, wherein the wiring structure includes a plurality of wirings,
the plurality of wirings include respective embedded parts embedded in the base,
the base has a plurality of recesses exposing the embedded parts of the plurality of wirings toward the plane surface, and
the base has a groove between recesses through which wirings having different potentials are exposed among the plurality of recesses.

8. The electronic control unit according to claim 1, wherein the wiring structure includes embedded parts embedded in the base, and
the embedded parts of the wiring structure are disposed at positions of the same depth from the plane surface of the base in a single-layer structure.

9. The electronic control unit according to claim 1, wherein the connector module is disposed such that the plane surface of the base faces the board module.

10. The electronic control unit according to claim 1, wherein the connector module enables electrical connection to a power supply,
the board module is provided with a power conversion circuit unit and a control circuit unit on the board, the power conversion circuit unit converting power supplied from the power supply via the connector module and the control circuit unit controlling driving of the power conversion circuit unit,
the power conversion circuit unit is disposed on one side of the board, and
the control circuit unit is disposed on the other side of the board.

11. The electronic control unit according to claim 1, wherein the connector module enables electrical connection to a power supply,
the board module is provided with a power conversion circuit unit on the board, the power conversion circuit unit converting power supplied from the power supply via the connector module, and
the electronic components include switching elements that cut off a current in a case where the power supply is connected to have a reverse polarity or in a case where a short circuit occurs in the power supply.

12. The electronic control unit according to claim 11, wherein
the switching elements are configured as FETs.

13. The electronic control unit according to claim 11, wherein the wiring structure includes control wirings functioning as control lines for controlling the switching elements, and
the control wirings have connection portions protruding from the base toward the board module for connection to a control circuit unit of the board module, and the connection portions of the control wirings are located at an outer circumferential portion of the base.

14. The electronic control unit according to claim 11, wherein
the electronic components further include filter elements constituting a filter circuit that suppresses noise of power flowing to the power conversion circuit unit, and
the filter elements are disposed closer to the power conversion circuit unit than the switching elements.

15. The electronic control unit according to claim 1, wherein the connector module enables electrical connection to sensors,
the wiring structure includes signal wirings functioning as signal lines for transmitting detection signals of the sensors,
the signal wirings have connection portions protruding from the base toward the board module for connection to a control circuit unit of the board module, and
the connection portions of the signal wirings are located at an outer circumferential portion of the base.

16. The electronic control unit according to claim 10, wherein the power conversion circuit unit of the board module converts DC power supplied from the power supply into AC power, and
the board module supplies the AC power converted by the power conversion circuit unit to the outside without passing through another board module other than the board module.

17. The electronic control unit according to claim 1, further comprising a mounting base on which the board module and the connector module are mounted,
wherein the board module and the connector module are stacked on the mounting base in this order, and
the board module is fixed by sandwiching the board between the mounting base and the connector module.

18. The electronic control unit according to claim 17, wherein the mounting base has a plurality of mounting supports supporting the board module and the connector module,
the connector module has a plurality of mounting support columns erected at positions corresponding to the plurality of mounting supports of the mounting base, respectively,
each of the plurality of mounting support columns includes a cylindrical support main body integrated with the base and a metal bush integrally molded inside the support main body,
the bush has a cylindrical portion located on an inner circumferential side of the support main body and an annular flange portion protruding from a distal end of the cylindrical portion toward an outer circumference, and
the flange portion of the bush abuts on the board of the board module.

19. The electronic control unit according to claim 1, wherein the wiring structure includes a plurality of wirings;
the connector module further includes a conductive jumper member bonded to the wiring structure in a state where the jumper member is placed on the plane surface of the base, and
the jumper member is bonded to two wirings, among the plurality of wirings of the wiring structure, in a state where the jumper member is bridged between the two wirings.

20. The electronic control unit according to claim 17, wherein the connector module includes connector units protruding from a surface opposite to the plane surface,
the electronic control unit further comprises:
a cover in a form of a cylinder having a bottom covering the board module and the connector module and mounted around an outer circumferential portion of the mounting base in a state where the connector units of the connector module are exposed to the outside via an opening;
a first seal member sealing a gap between the surface of the connector module and a bottom surface of the cover; and
a second seal member sealing a gap between an outer circumferential surface of the mounting base and an inner surface of an outer circumferential portion of the cover, and
the cover is fixed by caulking the outer circumferential portion of the cover, in a state where the bottom surface of the cover presses the first seal member against the connector module, such that the outer circumferential portion of the cover is pressed against the outer circumferential surface of the mounting base.
